(19) United States
(12) Patent Application Publication
(10) Pub. No.: US 2001/0050993 A1
(43) Pub. Date: Dec. 13, 2001

(54) ACTIVE NOISE REDUCTION APPARATUS HAVING A HEADSET WITH DUAL STEREO JACKS AND AN ELECTRONIC DEVICE HAVING SWITCH MEANS

(76) Inventor: ANDREA DOUGLAS, OLD BROOKVILLE, NY (US)

Correspondence Address: FROMMER LAWRENCE & HAUG, 745 FIFTH AVENUE- 10TH FL., NEW YORK, NY, 10151, US

(21) Appl. No.: 09/041,291

(22) Filed: Mar. 12, 1998

Related U.S. Application Data
(60) Provisional application No. 60/041,400, filed on Mar. 19, 1997.

(51) Int. Cl. H03B 29/00; G10K 11/16

(52) U.S. Cl. 381/71.6

(57) ABSTRACT

An universal active noise reduction apparatus having a headset and a separate electronic sound module, comprising the headset having a housing, whereby the housing having a headband with a first end and a second end; a plurality of earcups having a microphone means for detecting noise signal and a speaker means for receiving audio signals attached to both ends of the headband; electronic connecting means having a first end and a second end, whereby the first end of the electronic connecting means extends from at least one earcup of the headband; an adapter connected to the second end of the electronic connecting means, whereby a plurality of male jacks for transmitting the audio signal protrude from the adapter; the electrical sound module containing a noise reduction circuitry means and an amplifier means, whereby the electrical sound module has at least a plurality of female members that interface with the male jacks of the adapter when inserted into the module for transmitting sound means; and optionally a switch means located on the electrical sound module that activates the active noise reduction circuitry means to cancel background noise prior to being transmitted to a ear of the wearer.

### FIELD OF THE INVENTION

This invention relates to a novel active noise reduction headset having a single connector with dual jacks for independently interfacing with separate electronic devices, such as radios, compact discs, tape players or in-flight entertainment for reducing background noise outputted to the user's ear. This novel active noise reduction headset provides a quiet zone within the two earcups and independently calibrates the headset sensors, which allows for universal compatibility with any electronic devices having sound applications. Accordingly, the present active noise reduction headset incorporates the leads from the left and right microphones; the leads from the left and right audio interfaces and the leads from the left and right grounds into a single stereo connector having dual plugs for insertion into a communication device containing active noise reduction circuitry and being enabled by switch means installed in the device.

### BACKGROUND OF THE INVENTION

As is to be appreciated, in numerous situations, the presence of background acoustic noise is undesirable. As an example, consider the situation in which an airline passenger is attempting to listen to an in-flight entertainment program, while sitting next to passengers engaged in a loud and noisy conversation. Thus, the passenger wearing a standard headset constantly hears the noise from the passengers sitting near by and, any ambient noise from the humming of the engines or the like. This passenger is distracted and unable to concentrate on the in-flight program and often the sound being transmitted from the in-flight program to the listener is impaired.

In an attempt to reduce background noise so as to improve the intelligibility of electro-acoustic communication using headsets with a microphone, a technique has been developed, called active noise reduction which refers to any electro-acoustical method in which a undesired sound wave is canceled by a second sound wave that has the same amplitude but is 180 degrees out of phase. An active noise reduction apparatus, such as a headset, utilizes a sensor microphone placed at the ear in the sound field of the speaker, and which senses the background noise and generates the second sound wave 180° degrees out of phase. With this active type headphone device, a negative feedback loop is used whereby the electrical signals converted from the external noises by a microphone unit are fed back in a reverse phase for reducing the noise in the vicinity of the headphone unit. A feedback circuit utilizing a closed loop system as shown in the prior art provides a “quiet zone” between the speaker and the ear which eliminates the background noise. This is because in a noisy environment, the ear will detect not only the output of the speaker, but also the background noise.

However, there exist various disadvantages in the conventional active noise reduction systems. The prior active noise cancellation systems, for instance, utilize closed loop-type circuits governed by the associated equations:

$$P = S ( \frac{{H}_{1} {H}_{2} + {H}_{2}}{1 + {BH}_{1} {H}_{2}} ) + N ( \frac{1}{1 + {BH}_{1} {H}_{2}} )$$

where

P=output

S=standard audio signal

H₁=high pass filter

H₂=speaker at headset

N=noise component

B=variable gain

The conventional closed loop noise reduction system contained within the noise reduction headset, is not ideal as a very large direct transmission gain (1+BH1H2) is required in order to reduce the noise component (N) to zero at the output (P). This system suffers from the problem of instability. This creates drawback of oscillation, i.e., squealing due to the unstable loop conditions caused by variations in the transfer function of the speaker, feedback microphone and acoustic cavity containing these elements and user headgear. The degree of noise cancellation generated by the conventional closed loop noise reduction device, at any frequency, is directly related to the direct transmission gain at that frequency. However, the higher the gain the more susceptible the device is to instability.

The conventional active noise reducing headphone device also has the drawback that when mechanical vibrations such as impact, frictional induced vibrations from connecting cords, user jaw movement induced vibrations etc., are transmitted to the noise feedback microphone, these vibrational noises are converted to electrical signals by the microphone. These signals conveyed in the conventional active noise reducing headphone are amplified and cause instability and other non-linear effects, for example, audio interruption, loud noises or pressure surges.

Another drawback of conventional active noise reducing headphone devices is the complexity added to the device to avoid canceling the desired audio signal, which signal is inputted as an electrical signal. The desired audio signal (S) of the conventional device is input into two summing nodes to create the signal transmitted to the user's ear. The first summing node adds the negative feedback microphone signal to the desired input audio signal. But, in a conventional closed loop feedback device, the signal feedback from the microphone contains the desired audio signal as well as the ambient noise signal which is desired to be canceled. This feedback signal is subtracted from the desired input audio signal to create the anti-noise signal, with zero desired audio signal content. Then, a second summing node is used to add the desired audio signal back into the loop so it can be transmitted to the output transducer. This method of generating the desired audio signal adds complexity and cost to the conventional noise reducing device. The additional summing node processing in the conventional device also increases chances of creating distortion in the desired audio signal as well as increasing the possibility of instability.

In addition, various other prior art headphone configurations have been developed for creating an active noise reduction device, where the input and output transducers are positioned in relation to the ear. Thus, in general, the prior art is concerned with the location of the speaker, being the output transducer, and the microphone, which is input transducer, being in the same plane or substantially aligned in the same plane with the headphone. Therefore, the processed signal output generated from this arrangement is substantially in the same time domain as the original acoustic wave, that is the signal is in phase. Furthermore, the prior art ANR headphones have the microphones and noise reduction circuitry located within the headphone with a single jack comprising the leads from the right and left audio interface and the lead from the ground interface.

Accordingly the prior art headphone having the microphone circuitry installed in the headphone must be compatible or manually calibrated to interface with multimedia sound devices, such as radio, compact disc, or tape players. If not, different hardware or a wire configuration is required to ensure enhanced sound performance, ANR operation, is achieved in the conventional headsets. Standard electric microphones located in the conventional headset and other external peripheral equipment are often reconfigured to execute these ANR and sound applications. Often, an adaptor or converter is necessary to supply the uniform power to the microphones in the conventional headsets to send the appropriate signal to the sound card or audio adapter card of the computer or to other electronic sound devices.

Thus, the prior art has failed to provide a relatively low-cost active noise reduction headset having no noise reducing circuitry, but having the ability to interface with electronic sound devices containing such circuitry for reducing background noise to an acceptable level. The prior art has further failed to provide a universal active noise reduction headset that adapts to an electronic sound device having a switch mode to activate the active noise reduction circuitry to transmit sound transmissions without distortion from background noise or to activate standard audio output transmission from conventional headsets.

A major advantage of the present invention over the prior art is that any headset that utilizes the present invention will be compatible to the electronic switch means of the present invention that is installed in any electronics having sound output without the need to purchase additional convertor means or to undergo independent calibration means. It is not known in the prior art to provide a novel active noise reduction headset that has a novel interface which adapts to an active noise reduction ready mode in a separate electronic device, such as a compact disc player, a tape player, a radio or an in-flight armrest. It is also not known to provide a novel switch means in an existing electronic sound device so that the user can utilize the headset of the present invention and activate the active noise reduction from the outputs of the pick-up microphones or opt to utilize one or more audio outputs from a standard headset for conventional sound transmissions.

### OBJECTS AND SUMMARY OF THE INVENTION

An object of the present invention is to provide a novel active noise reduction headset having a single interface with dual plugs that contain the outputs from the microphone means and audio output means for adaption into an electronic means or computer sound means incorporating the active noise circuitry for reducing noise which overcomes the problems associated with the prior art.

Specifically, it is an object of the present invention to provide a active noise reduction headset which has the circuitry means located remote from the headset, but providing the ability to interface with the microphone and audio outputs from the left and right ear of the wearer by dual plugs located in a single connector extending from the headset by a single lead.

More specifically, it is object of the present invention to provide a universal active noise reduction headset having a single connector comprising two grounds, two audio inputs and two audio outputs that connects into a electronic interface, such as a compact disc interface, which has a switch mode to allow the user to activate the active noise circuitry or standard circuitry, which is relatively inexpensive.

It is still an object of the present invention to provide a relatively low-cost novel active noise reduction headset that independently calibrates the components of the headset with a standard electrical assembly so that there is ANR headset compatibility with all electronic assemblies.

Another object of the present invention is to create a relatively low-cost active noise reduction headset method of producing an external noise signal having a gain and phase response detected by a pick-up microphone in the headset assembly; inputting the external noise signal received by the microphone through electro-acoustic processing means in the standard electrical assembly to produce an electro-acoustical anti-noise signal having an equal gain and opposite phase response to the external noise signal; and balancing the gain response of the anti-noise signal by amplitude adjustment means to match the gain response of the external noise signal to yield a theoretical zero at the predetermined point.

An another aspect of the present invention is that the output transducer and microphone utilized in the open loop active noise reduction of the present headset has the capability to transmit the original input audio signal to the speaker without the re-addition of the input audio signal.

An aspect of this invention is to provide a user friendly active noise reduction headset that is adaptable to any electronic devices having an active noise reduction “ready mode” for increasing the flexibility of multimedia applications that can be utilized with a headset made in accordance with the present invention and to decrease the cost of manufacturing active noise reduction headsets. The active noise reduction headset has at least one earcup, at least one noise canceling microphone, at least one acoustical waveguide, and at least one output transducer, lead cables extending from the microphone(s), leads extending from the input transducer(s), and leads extending from the ground interface, a single stereo for assembly of all the leads, and dual jacks extending from the connector. The active noise reduction interface is comprised of active noise reduction circuitry, a switch activating the ANR mode or the standard audio output mode. The universal active noise reduction apparatus having a headset and a separate electronic sound module, comprising: the headset having a housing, whereby the housing having a headband with a first end and a second end; a plurality of earcups having a microphone means for detecting noise signal and a speaker means for receiving audio signals attached to both ends of the headband; electronic connecting means having a first end and a second end, whereby the first end of the electronic connecting means extends from at least one earcup of the headband; an adapter connected to the second end of the electronic connecting means, whereby a plurality of male jacks for transmitting the audio signal protrude from the adapter; the electrical sound module containing a noise reduction circuitry means and an amplifier means, whereby the electrical sound module has at least a plurality of female members that interface with the male jacks of the adapter when inserted into the module for transmitting sound means; optionally a switch means located on the electrical sound module that activates the active noise reduction circuitry means to cancel background noise prior to being transmitted to a ear of the wearer. The preferred speaker means does not require amplitude adjustment means for creating a quiet zone. In addition, the preferred electronic sound module is a compact disc player.

Other objects, features and advantages according to the present invention will become apparent from the following detailed description of the illustrated embodiments when read in conjunction with the accompanying drawings in which corresponding components are identified by the same reference numerals.

### BRIEF DESCRIPTION OF THE DRAWINGS

FIG. 1 is a perspective side plan view of the active noise reduction headset without any active noise reduction circuitry;

FIG. 2 is a perspective plan view of the active noise reduction headset without any active noise reduction circuitry;

FIG. 3 is a perspective plan views of the active noise reduction headset of the present invention and standard prior art headsets showing interfacing with the electronic sound means with a switch means;

FIG. 4 is a diagram of the lead wires and connections extending from the active noise reduction headset of the present invention and the lead wires and connections extending from the standard prior art headsets and the circuitry contained within the electronic sound means;

FIG. 5 is a diagram of the input and output connections of the electronic sound means including the amplifier means and ANR circuitry.

### DETAILED DESCRIPTION

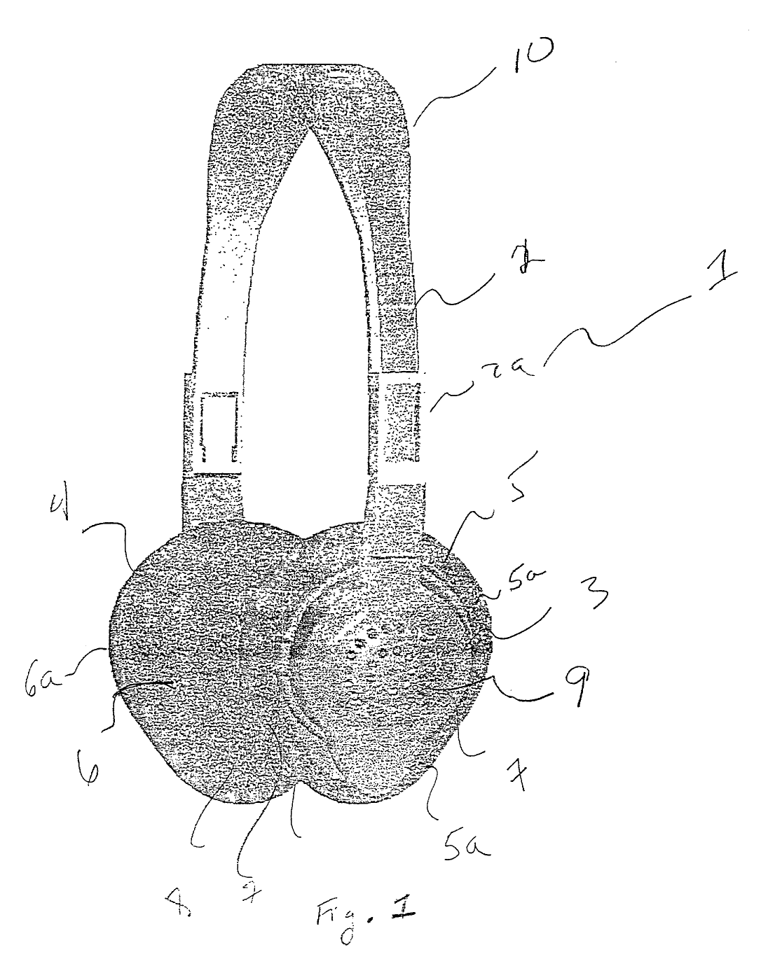

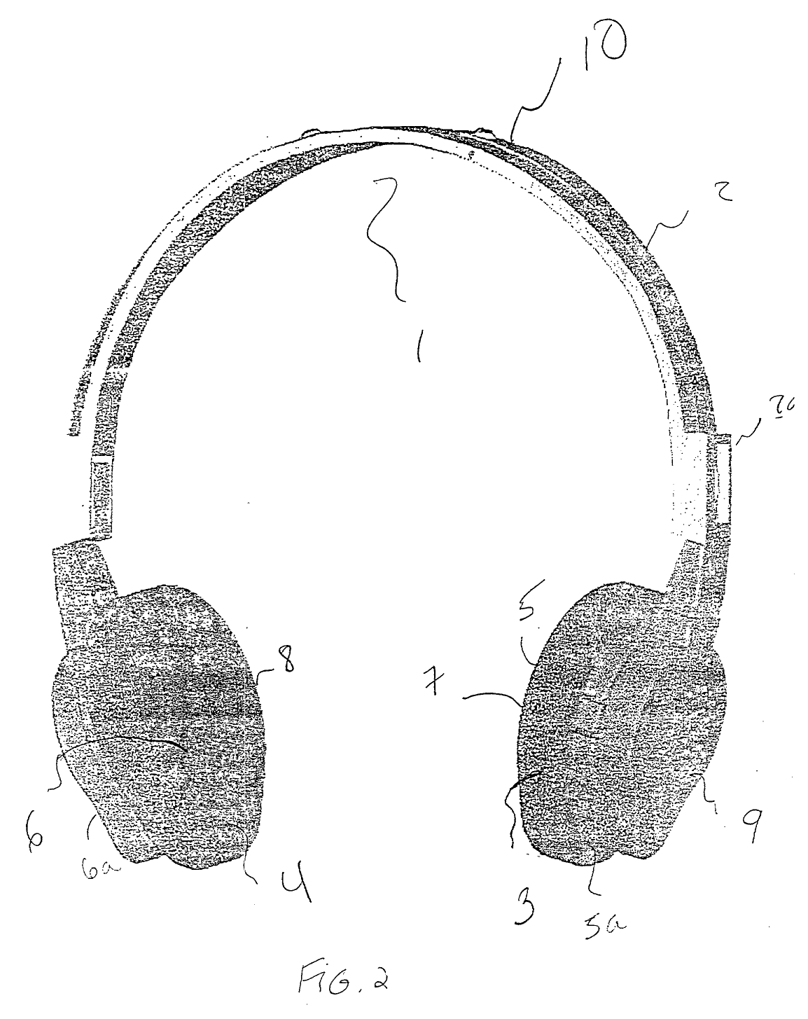

FIGS. 1 and 2 illustrate an active noise headset 1 made in accordance with the present invention having a housing 10 comprised of a headband 2 with adjustable means 2A to secure the headset to any size or shape of wearer's head, a left earcup 3, and a right earcup 4, and electronic connecting means (not shown). The left and right earcups 3, 4 each have inner surfaces 5, 6 and outer surfaces 5A, 6A. The inner surfaces 5, 6 of the left and right earcups 3, 4 are covered by an acoustical material 7, 8 respectively. The preferred material is called “Slo-Flo” foam and it is of such a density and construction so as to define a noise-free response and to deaden any sound reflections returning to the microphone (not shown), acting as an acoustical filter, from the listener's face and/or ear; whereas the prior art uses a negative feedback of the signal from the microphone, no such feedback is produced in the present invention. This resilient acoustic material is preferably positioned between the speaker/microphone (not shown) and the ear to create a quiet zone.

This waveguide is preferably more than just the usual rubber sponge which is commonly provided on earphones for comfort purposes. Instead, an open-loop arrangement as utilized in the present invention, there is no need to add another audio signal, as the original input audio signal is transmitted to the speaker, as the signal has not been disturbed by the open loop system. The acoustic waveguide (not shown) couples the user ear to the output transducer for increased speaker efficiency. This positioning of the sensor microphone (not shown) in a plane outside the plane of the speaker or output transducer (not shown) allows for a close distance to the quiet zone for accurate phase agreement between noise and anti noise signals. In addition, the placement and orientation of the sensor microphone minimizes microphone sensitivity lobe patterns in the direction of the speaker sound field. The sensor microphone used in the active noise reduction apparatus is preferably an omnidirectional microphone, which is receptional to noise from all angles. This characteristics of the sensor microphone allows flexibility in the positioning of the microphone with the earpiece of the headset.

As shown in FIGS. 1 and 2 therein, the left and right earcups 3, 4 each have acoustical port holes 9 (shown only for left earcup) on the outer surfaces 5A, 6A. The housing 10 can be comprised preferably of injected molded plastic material or the like.

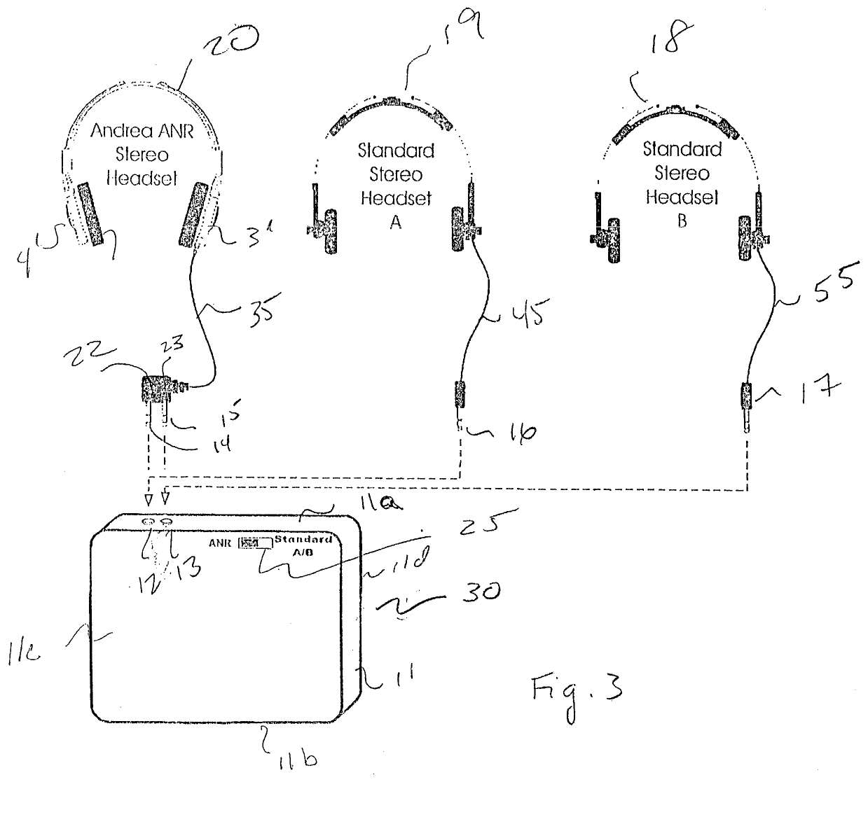

In FIG. 2, the active noise reduction headset 1 is shown having the acoustical materials 7, 8 that form acoustical waveguides (not shown) completely covering the inner surfaces 5, 6 of the earcups that face towards the ear canal of the wearer. A pick-up microphone (not shown), preferably any omnidirectional type microphones, and output transducer (not shown) is located in each of the left and right earcups 3, 4. The acoustical materials 7, 8 can be located between the output transducer (not shown) and the eardrum of the user to create an acoustical waveguide for the transducer by coupling the audio signal to the ear of the user. The output transducer (not shown) converts electric signals received from any multimedia system or module 30 (FIG. 3) into sound waves to be conveyed directly into the entrance of the wearer's ear canal by a multiple of acoustical port holes 9 located on the earcup.

The port holes inner side cups in the speaker grill of FIGS. 1 and 2 in the earcup allow the audio sound to be transmitted directly to the canal of the user's ear without the necessity of an ear tube. Hence, as a result of the earcups 3, 4 having preferred arcuate shape, the earcups 3, 4 fits snugly over the wearer's outer ear, with no tubular passage is needed for conveying the sound from the receiver or transducer to the ear canal of the wearer.

The acoustical materials 7, 8 of the earcups 3, 4 shown in FIGS. 1 and 2 preferably surrounds the output transducer (not shown) and the microphone (not shown) and acts as an acoustic barrier or filter between the transducer and microphone in each earcup to decrease the open loop gain by placing an acoustical impediment in the path of the microphone and the output transducer. The acoustical materials 7, 8 of the headset 1 form an enclosure which fits respectively around each ear of the wearer to isolate the desired original inputted audio signal (from the independent electronic sound device) from the noise detected and canceled by the pickup microphone located in each earcup.

As shown in FIG. 3, the active noise reduction headset 20 and two conventional headsets 19, 18 are shown interfacing with a separate and independent electronic sound module 30 having a switch means 25 made in accordance with the present invention. The electronic sound device or module 30 is preferably a compact disc player, a cassette player, a radio, or in-flight entertainment device. The sound module 30 is comprised of a housing 11 having a top surface 11A, a bottom surface 11B, a first side surface 11C and a second side surface 11D. The top surface 11A of the housing 11 of the sound device 30 contains two female connector members 12, 13 for receiving at least one male cable jack from the dual jacks 14, 15 of the stereo connector 22 of the active noise reduction headset 1 of the present invention or a single jack 16, 17 from the two standard headsets 18, 19 or other multimedia devices.

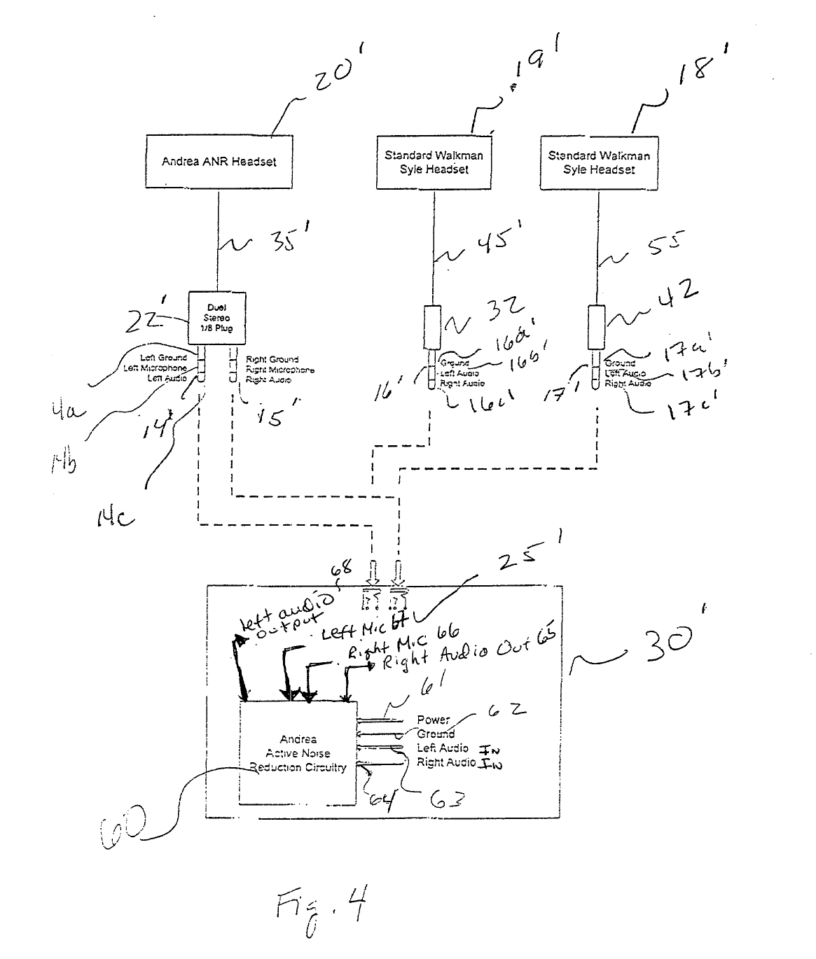

As shown in FIG. 3, the electrical connecting means 35 extends from the lower portion of either the right earcup 4′ or the left earcup 3′ (as shown). The stereo connector 22 is comprised of a housing 23 containing the contact from the right and left pick-up microphone lead wires (not shown) in the earcups; contact from the output wires from the left and right receiver means (not shown), as well as contact from the ground wires from the left and right earcups grouped in the electronic connecting means cable 35 as shown in FIG. 4. The signals are transmitted from the contacts at the tip of the stereo connector 35 to the electronic circuitry contained in the module 30, preferably for reducing background acoustic noise and outputting sound to the wearer's ear.

The inventive headset 20 is designed preferably so that the pick-up microphone (not shown) is acoustically arranged to detect the background noise signal in the vicinity of the ear and conveyed to the dual jacks 22, 23 of the stereo connector when interfaced with the module 30. This noise signal will be inverted through electric-acoustical processing means located in the module 30 to produce an anti-noise signal in the earcup, which signal is transmitted to the acoustical waveguide to create a quiet zone near the wearer's ear canal, provided that the switch means 25 is in the active noise reduction mode (shown). This quiet zone is located between the output transducer and the eardrum of the user in each earcup 3′, 4′.

In FIG. 4, a diagram of the components of the headsets 20′, 19′, 18′ and the sound module 30′ containing the active noise reduction circuitry and the switch means 25′ are shown. The active noise reduction headset 20′ of the present invention comprises cable wiring 35′ extending downwardly from one of the earcups leading to a stereo connector or adapter 22′. The preferred adapter is a dual stereo 3 mm plug. The connector 22′ has two stereo miniplugs or jacks 14′, 15′, respectively, shown in FIG. 4. The first jack 14′ contains the signals or contacts from the left ground 14A, the left microphone 14B, and the left audio 14C transmitted by cable wiring 35′ from the left earcup 3′, which are inputted into the sound module 30′. Likewise, the second jack 15′ contains the signals or contacts from the right ground 15A, the right microphone 15B, and the right audio 15C transmitted by cable wiring 35′ from the right earcup 4. The signals on the tip of the dual jacks 14′, 15′, respectively are transmitted to the module 30′ when the jacks are plugged into its appropriate female members 12, 13 and either undergo noise reduction or standard electrical-acoustic processing to output sound to the ears of the user depending on the switch means 25′ mode. That is, the user can either plug in a maximum of two headphone jacks form a walkman headset 32, 42 or plug in a ANDREA headset 20′ having two jacks 14′, 15′ and by flipping the switch 25 in FIG. 3 to the ANR mode, an active noise reduction headset of the present invention is utilized. Accordingly, the connector or adapter 22′ connects the present headset 20 to external communication equipment. It is the function of the switch means 25′ to dictate whether the user will opt to cancel background noise or not when listening to audio applications in a noisy environment.

The two conventional headsets 19′, 18′ are connected by cable wires 45′, 55′, respectively into adapters having a single jack. That is, in the first conventional headset 19′ a cable wire 45′ extends into the first adapter 32 which has a jack 16 comprising a ground output 16A′, a left audio input 16B′, and a right audio input 16C′. Similarly, the second conventional headset 18′ includes a cable wire 55′ extending into a second adapter 42 having a jack 17 comprising a ground output 17A′, a left audio input 17B′, and a right audio input 17C′. Either jack 16′ or jack 17′ in combination or individually can be inserted into the module 30′ of the present invention having a switch means, which enables two headset users to listen simultaneously to the output from the compact disc player when the switch means is in the “STANDARD A/B” mode displayed in FIG. 3.

As shown therein, the active noise reduction circuitry 60 inside the independent electronics module 30′ generally includes at least one power input 61, at least one ground input 62, at least two audio inputs having a left audio input 63 and a right audio input 64, at least two audio outputs having a left audio output 68 and a right audio output 65, and at least two microphone outputs 66, 67 as shown in FIG. 4.

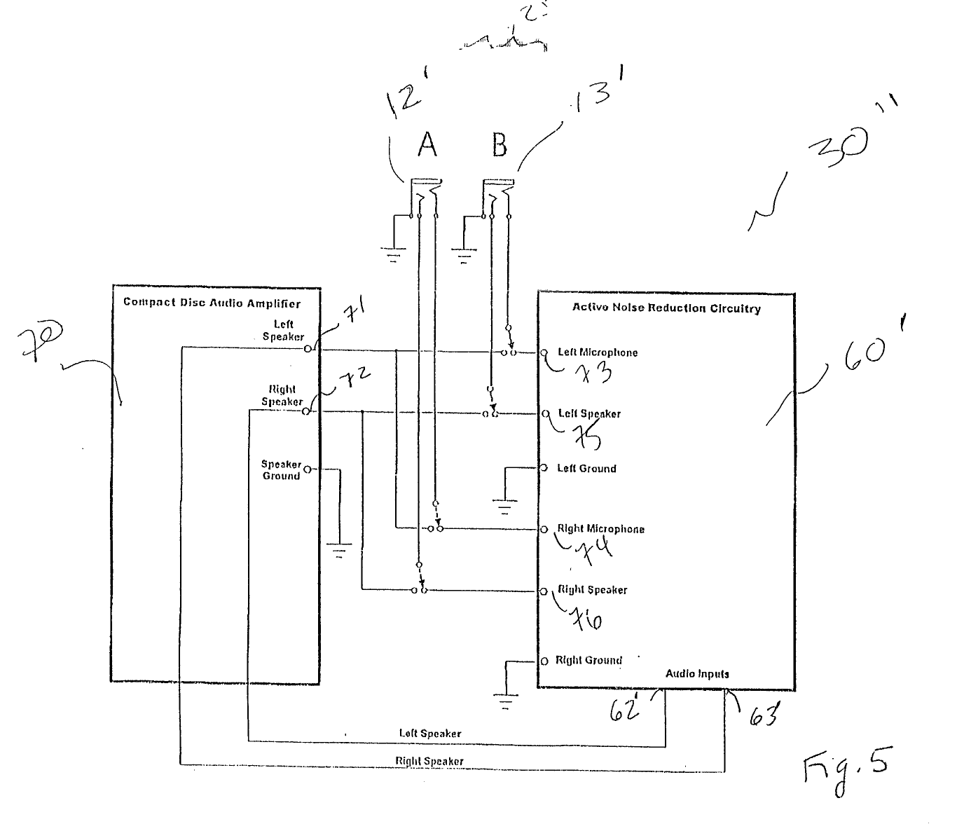

FIG. 5 illustrates the wiring of the circuit card assemblies of the switch means 25″ and active noise reduction circuit 60′ and the amplifier of electronic sound module 30. The amplifier preferably being a compact disc audio amplifier 70 inside the module 30″. When the switch 25′ is in the “ANR” mode, the active noise reduction circuitry 60′ detects an external noise signal by the audio inputs 62′, 63′ of each pickup microphones 73, 74 located in the earcups, the noise signal is processed to produce an anti-noise and the gain of the signal is adjusted by amplitude adjustment means, which includes the calibration pot (not shown) and capacitor (not shown) located in the earcup, to match the gain and phase response of the electro-acoustic signal to yield a theoretical zero at a point called the quiet zone. The amplitude adjustments means is preferably a magnitude adjustment potentiometer RA, which may be adjusted or set during the initial assembly thereof or alternatively may be obtained electrically. However, phase adjustment is not necessarily possible at all frequencies.

Therefore, the noise reduction apparatus of the present invention contains a headset, which provides superior rejection of unwanted background noise and excellent voice response by interfacing with the electronic sound module of the present invention having an “ANR” mode engaged by a switch system. The signals from the input dual jacks 14′, 15′ of the stereo adapter are plugged into the female members 12′, 13′ and thereby connected by the circuitry contained in the module 30″ that consists of an amplifier 70 to amplify the electrical signal before being transmitted to the left and right speakers 71, 72 and then as sound to the listener's ears. Such circuits enable by amplitude adjustment means, allow the user to adjust the audio to the left and right speakers.

The circuit board may contain additional circuit elements for processing the signals received from at least two preferred noise reducing microphones inserted into the input external interface 30″ and for amplifying signals for supply to the speaker as described in U.S. patent application Ser. No. 08/339,126 filed Nov. 14, 1994 (PCT No. US95/14756 filed Nov. 14, 1995) and U.S. patent application Ser. No. 08/485,047filed Jun. 7, 1995, which have a common assignee with the present application, and both applications which are incorporated by reference herein.

The present invention is not so limited to headsets or speakers, but can be used with numerous other computer accessories for computer audio transmission, such as noise cancellation earsets described in U.S. patent application Ser. No. 08/535,353 filed on Oct. 23, 1995, which has common assignee with the present application, and the application is incorporated by reference herein.

The universal active noise reduction apparatus comprising a headset and separate electronic sound module described above is simple in construction, lightweight and portable, enabling it to be used with maximum convenience and ease for the user in assembling the necessary cable connections. Thus, it is seen that the present invention provides a low-cost active noise reduction headset without containing the electronic circuitry, but still having the ability to interfaces with any electronic sound modules for audio communication to the ear of the listener. The present invention also relates to installing a switch means described in FIG. 5 in already existing compact disc players, tape players, or radio players to be able to activate the active noise reduction circuitry when the present headset is interface with the sound modules. This novel switch means 25′ increases the apparatus' flexibility and decreasing the amount of cable connections required. In addition, the placement of the dual jacks 14′, 15′ containing the signal from the left and right microphones, respectively provides easy access for assembling the headset to the multimedia sound applications and alleviates the room constraint on the front of any electrical modules.

As is to be appreciated, by using the above-described apparatus and devices for transmitting sound from a compact disc player, tape player, or radio through the use of headsets without the distortion of background noise, the need for reconfiguring the headset or utilizing a converter is alleviated. Thus, the wearer can count on an overall savings with minimal cost associated with constructing such an apparatus. Further, the cost of producing such an effective headset is minimized as the cost of producing the circuitry is now tied into the independent electronic means. As a result, the electronics module of the present invention is universal with any conventional headsets or with a noise reduction “ready” headset.

Furthermore, although preferred embodiments of the present invention and modifications thereof have been described in detail herein, it is to be understood that this invention is not limited to those precise embodiments and modifications, and that other modifications and variations may be affected by one skilled in the art without departing from the spirit and scope of the invention as defined by the appended claims.

What is claimed is:

1. An universal active noise reduction apparatus having a headset and a separate electronic sound module, comprising:
the headset having a housing, whereby the housing having a headband with a first end and a second end;
a plurality of earcups having a microphone means for detecting noise signal and a speaker means for receiving audio signals attached to both ends of the headband;
electronic connecting means having a first end and a second end, whereby the first end of the electronic connecting means extends from at least one earcup of the headband;
an adapter connected to the second end of the electronic connecting means, whereby a plurality of male jacks for transmitting the audio signal protrude from the adapter;
the electrical sound module containing a noise reduction circuitry means and an amplifier means, whereby the electrical sound module has at least a plurality of female members that interface with the male jacks of the adapter when inserted into the module for transmitting sound means; and
optionally a switch means located on the electrical sound module that activates the active noise reduction circuitry means to cancel background noise prior to being transmitted to a ear of the wearer.

2. The universal active noise reduction apparatus of claim 1, wherein no amplitude adjustment means is required for creating a quiet zone.

3. The universal active noise reduction apparatus of claim 1, wherein the electronic sound module is a compact disc player.
